(19) United States
(12) Patent Application Publication
(10) Pub. No.: US 2007/0241444 A1
(43) Pub. Date: Oct. 18, 2007

(54) CARRIER BOARD STRUCTURE WITH CHIP EMBEDDED THEREIN AND METHOD FOR FABRICATING THE SAME

(75) Inventors: Shih-Ping HSU, Hsin-chu (TW); Chung Cheng Lien, Hsin-chu (TW); Zhao Chong Zeng, Hsin-chu (TW); Shang Wei Chen, Hsin-chu (TW)

Correspondence Address: SAWYER LAW GROUP LLP, P O BOX 51418, PALO ALTO, CA, 94303, US

(73) Assignee: PHOENIX PRECISION TECHNOLOGY CORPORATION, Hsin-chu (TW)

(21) Appl. No.: 11/734,768

(22) Filed: Apr. 12, 2007

(30) Foreign Application Priority Data
Apr. 12, 2006 (TW) 095112958

(51) Int. Cl. H01L 23/52

(52) U.S. Cl. 257/692

(57) ABSTRACT

A carrier board structure with a semiconductor chip embedded therein and a method for fabricating the same are proposed. A rectangular cavity is formed at a predetermined position of the carrier board, and at least a breach is formed at a corner of the rectangular cavity, wherein the breach is composed of a plurality of drilling holes. Thus, the breach is capable of providing the rectangular cavity with a larger space for receiving a semiconductor chip in the rectangular cavity, when in the process of disposing the semiconductor chip into the rectangular cavity.

### CROSS-REFERENCE TO RELATED APPLICATIONS

Under 35 U.S.C. §119, this application claims the benefit of priority to Taiwanese Application No. 095112958, filed Apr. 12, 2006, all of which is incorporated herein by reference.

### FIELD OF THE INVENTION

The present invention relates to carrier board structures with semiconductor chips embedded therein and methods for fabricating the same, and more particularly, to a carrier board structure formed with a cavity for embedding a semiconductor chip therein and a method for fabricating the same.

### BACKGROUND OF THE INVENTION

Due to the rapid growth in the electronic industry, the development of electronic devices has gradually shifted towards lightness, thinness, shortness, multi-functionality, high integration and low-profile. In order to satisfy the demand of high integration and miniaturization, semiconductor packages have evolved gradually from a single chip ball grid array (BGA) package or a flip chip (FC) package to a 3D packaging or a module packaging, giving the packaged structures a different appearance, such as System in Package (SiP), System Integrated Package (SIP) and System in Board (SiB).

These types of 3D or module packages typically utilize flip chip or wire bonding technology to electrically connect a semiconductor chip to a carrier board for mounting the semiconductor chip thereon, or mounting the semiconductor chip on the carrier board by using the Surface Mount Technology (SMT). By doing so, even the goal of providing a high number of I/O connections can be achieved, when operating at a high frequency or under a high speed, long conductive paths tend to stop the electrical performance of the packages from improving. In addition, since multiple interfaces are required in a traditional semiconductor package, fabricating costs are increased accordingly.

Accordingly, in order to effectively increase the electrical performance of the semiconductor packages for application in the products of next generation, a technology of embedding a semiconductor chip in a carrier board to achieve direct electrical connection is thus developed by the industry, so as to reduce the length of the conductive path, thereby reducing the loss of electrical signals and occurrence of signal distortion, and enhancing the capability of high speed operation.

As shown in FIGS. 1A and 1B, FIGS. 1A and 1B are a planar and a cross-sectional views of a conventional semiconductor package where a semiconductor chip is embedded in a chip carrier. As shown in the drawings, a rectangular cavity 101, formed in the carrier board 10, is provided to accommodate a semiconductor chip 12.

The rectangular cavity 101 is formed, according to the shape and size of the semiconductor chip 12 by mechanical or laser drilling. Although a cutter or a laser beam cuts the carrier board 10 along a predetermined cutting line in right-angle directions, the outer diameter of the cutter or the laser beam forms arc-shaped corners 102 in right-angle turns. The four corners of the semiconductor chip 12 are both right-angled, arc-shaped corners. When disposing the semiconductor chip 12 into the rectangular cavity 101, the right-angled corner of the semiconductor chip 12 may easily interfere with the arc-shaped corners 102 of the rectangular cavity 101. It thus causes difficulty in disposing the semiconductor chip 12 into the rectangular cavity 101. This even makes the semiconductor chip 12 unable to be received in the rectangular cavity 101 or protrude from the surface of the carrier board 10, when the position and angle of disposing deviate. When the semiconductor chip 12 is not properly received in the rectangular cavity 101 of the carrier board 10, the electrode pads of the semiconductor chip 12 will be mis-aligned, adversely affecting subsequent fabricating procedures. On the other hand, if the rectangular cavity 101 is too big, the gap between the gap between the rectangular cavity 101 and the semiconductor chip 12 may be too big. This will lead to the a reliability issue in the subsequent procedures caused by an excessive filling of adhesive, when filling in adhesive into the secured semiconductor chip 12 located between the semiconductor chip 12 and the carrier board 10.

Thus, how to solve the long existed problem mentioned above, which is in the prior art, has become a critical and desired issue for the packaging industry.

### SUMMARY OF THE INVENTION

In view of the above-mentioned drawbacks, a primary objective of the present invention is to provide a carrier board structure with a semiconductor chip embedded therein and a fabricating method thereof, so as to prevent the rectangular cavity from interfering with the semiconductor chip to be disposed into the rectangular cavity.

Another objective of the invention is to provide a carrier board structure with a semiconductor chip embedded therein and a fabricating method thereof, so as to allow the semiconductor chip to be disposed into the cavity of the carrier board without difficulty, thereby ensuring proper performance of subsequent procedures.

In order to achieve the foregoing and other objectives, the present invention proposes a carrier board structure with a semiconductor chip embedded therein which comprises a carrier board; at least one rectangular cavity formed in the carrier board; at least one breach formed at a corner or corners of the rectangular cavity, and the breach is composed of a plurality of drilling holes; and a semiconductor chip disposed into the rectangular cavity.

The plurality of drilling holes can be composed of at least a large drilling hole and at least two small drilling holes adjacent to the large drilling hole, at least a small drilling hole and at least two large drilling holes adjacent to the small drilling hole, or a plurality of large drilling holes. The drilling holes of the breach can be formed by means of a mechanical drilling process, a laser drilling process, or a pressing process. Thus, by the provision of the breach, problems resulting from arc-shaped corners of the rectangular cavity can be eliminated, and the semiconductor chip can be disposed into the rectangular cavity without problem. In addition, subsequent procedures are allowed to be performed as desired.

The present invention also discloses a carrier board structure, which comprises a carrier board; at least one rectangular cavity formed in the carrier board; and at least one breach formed at a corner or corners of the rectangular cavity, and the breach is composed of a plurality of drilling holes.

The present invention further provides a fabricating method of a carrier board with a semiconductor chip embedded therein. The method comprises the steps of: providing a carrier board; forming a rectangular cavity at a predetermined position of the carrier board; and forming at least a breach at a corner or corners of the rectangular cavity, and the breach is composed of a plurality of drilling holes.

The rectangular cavity can be formed by a mechanical drilling process or a laser drilling process. After the rectangular cavity is formed, the breach can be formed at any one, more than one, or each of the corners of the rectangular cavity by means of a mechanical drilling process, a laser drilling process, or a pressing process.

The fabricating method, according to another preferred embodiment of the present invention, comprises the steps of providing a carrier board; forming at least a breach at a corner or corners of a rectangular cavity to be formed in the carrier board, and the breach is composed of a plurality of drilling holes; and forming a rectangular cavity at a predetermined position of the carrier board.

Thus, the carrier board structure with a semiconductor chip embedded therein and the fabricating method thereof, according to the present invention, is capable of eliminating the arc-shaped corners of the rectangular cavity, such that the semiconductor chip can be disposed into the rectangular cavity without interference in the rectangular cavity.

### BRIEF DESCRIPTION OF THE DRAWINGS

The present invention can be more fully understood by reading the following detailed description of the preferred embodiments, with reference made to the accompanying drawings, wherein:

FIGS. 1A and 1B (prior art) are schematic planar and cross-sectional views showing a prior carrier board structure with a semiconductor chip embedded therein.

FIG. 2 is a schematic planar view showing the rectangular cavity formed in the carrier board in accordance the first preferred embodiment of the present invention;

FIGS. 3A to 3C are schematic planar views showing the formation of the breaches at the corners of the rectangular cavity of the carrier board in accordance with the first preferred embodiment of the present invention;

FIG. 4A is a schematic planar view showing a semiconductor chip being disposed into the rectangular cavity in accordance with the first preferred embodiment of the present invention;

FIG. 4B is a schematic perspective view showing the rectangular cavity of the carrier board with a semiconductor chip embedded therein in accordance with the first preferred embodiment of the present invention;

FIGS. 5A to 5C are schematic planar views showing the formation of the breach at the corners of the rectangular cavity in accordance with the second preferred embodiment of the present invention; and

FIG. 6 is a schematic planar view showing a semiconductor chip being disposed into the rectangular cavity in accordance with the second preferred embodiment of the present invention.

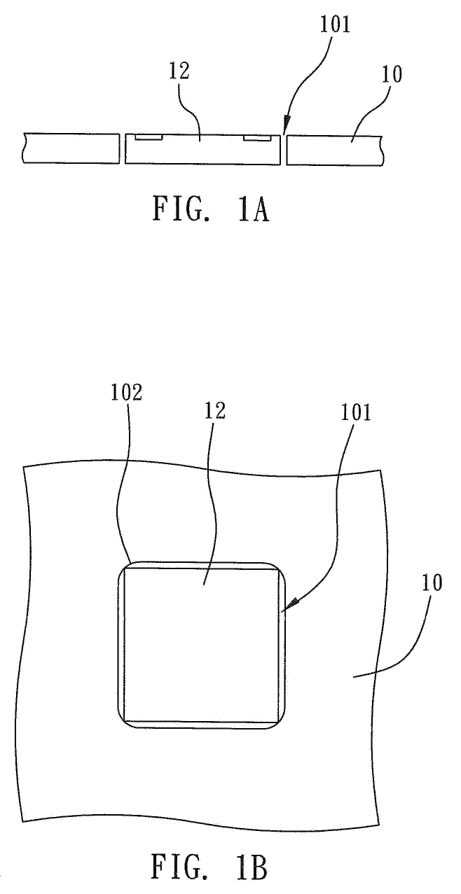

### DETAILED DESCRIPTION OF THE PREFERRED EMBODIMENTS

The present invention is described in the following with specific embodiments, so that one skilled in the pertinent art can easily understand other advantages and effects of the present invention from the disclosure of the invention. The present invention may also be implemented and applied according to other embodiments, and the details may be modified based on different views and applications without departing from the spirit of the invention.

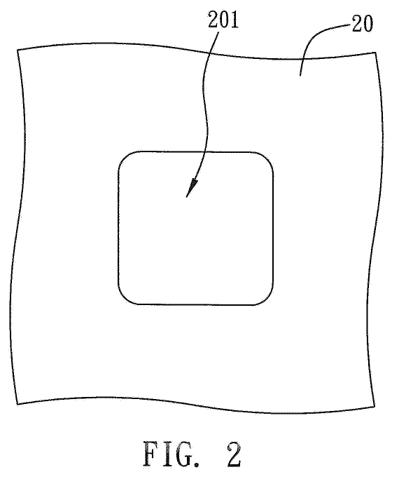

Referring to FIG. 2, FIGS. 3A to 3C and FIG. 4, FIG. 2, FIGS. 3A to 3C and FIG. 4 are the top views of a carrier board with a semiconductor chip embedded therein according to the first preferred embodiment of the invention.

As shown in FIG. 2, a carrier board 20 is provided, and a rectangular cavity 201 is formed at a predetermined position of the carrier board 20 through a cutting process along the predetermined cutting line by means of mechanical or laser drilling. The carrier board 20 is one selected from the group consisting of an insulation board, a metallic board, and a circuit board finished with front-end wiring processes.

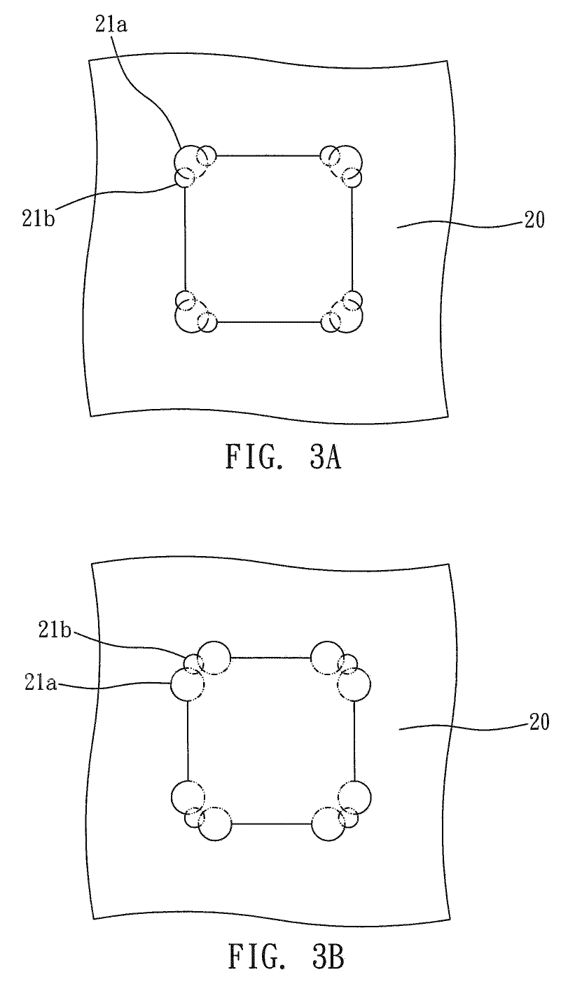

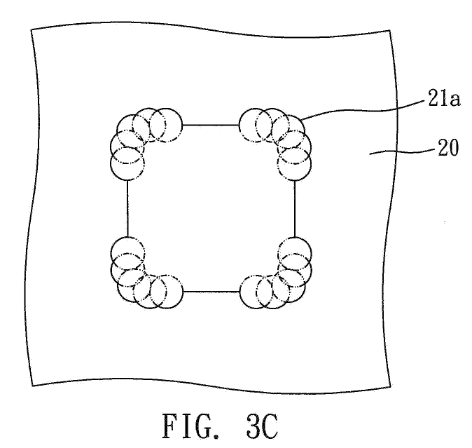

As shown in FIGS. 3A to 3C, breaches, which extend form the rectangular cavity 201, are formed at the corners of the rectangular cavity 201 by means of mechanical drilling, laser drilling, or pressing. The breach can be composed of a plurality of drilling holes formed by a combination of a large drilling hole 21a and two small drilling holes 21b adjacent to the large drilling hole 21a (as shown in FIG. 3A), or formed by a combination of a small drilling hole 21b and two large drilling holes 21a adjacent to the small drilling hole 21b (as shown in FIG. 3B) or formed by a plurality of large drilling holes 21a (as shown in FIG. 3C), so as to eliminate the arc-shaped corners, which are formed in process of cutting the rectangular cavity 201. It should be understood that the number of the breaches formed has no specific limitation; namely, the breach may be formed at a single corner, or more than one corner, or each of the four corners of the rectangular cavity 201.

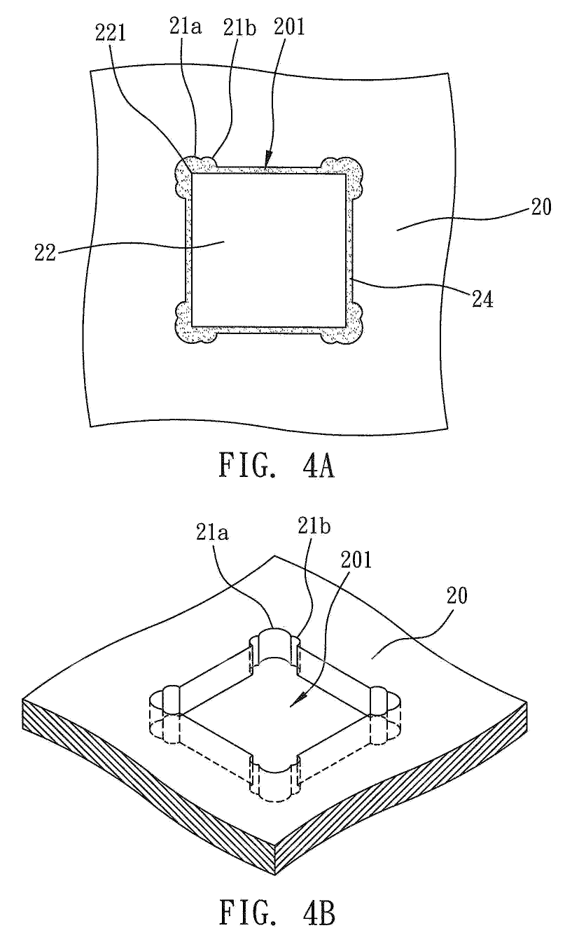

As shown in FIGS. 4A and 4B, which are illustrated based on the carrier board of FIG. 3A, a semiconductor chip 22 is disposed into the rectangular cavity 201. Because each of the corners of the rectangular cavity 201 forms a breach composed of a plurality of drilling holes, it forms a larger accessible space for the rectangular cavity 201 to accommodate the semiconductor chip 22. As a result, the corners 221 of the semiconductor chip 22 are allowed to be accommodated in either the large drilling holes 21a or the small drilling holes 21b, such that rectangular cavity 201 is not interfered with the semiconductor chip 22 at the time of disposing the semiconductor chip 22 into the rectangular cavity 201. Moreover, it is beneficial to the subsequent fabricating procedures.

A gap is formed between the periphery of the semiconductor chip 22 and the periphery of the rectangular cavity 201 of the carrier board 20, and is in a range of from 10 μm to 200 μm. The gap between the rectangular cavity 201 in the carrier board 20 and the semiconductor chip 22 is further filled with an adhesive material 24, so as to secure the semiconductor chip 22 in position in the rectangular cavity 201 of the carrier board 20.

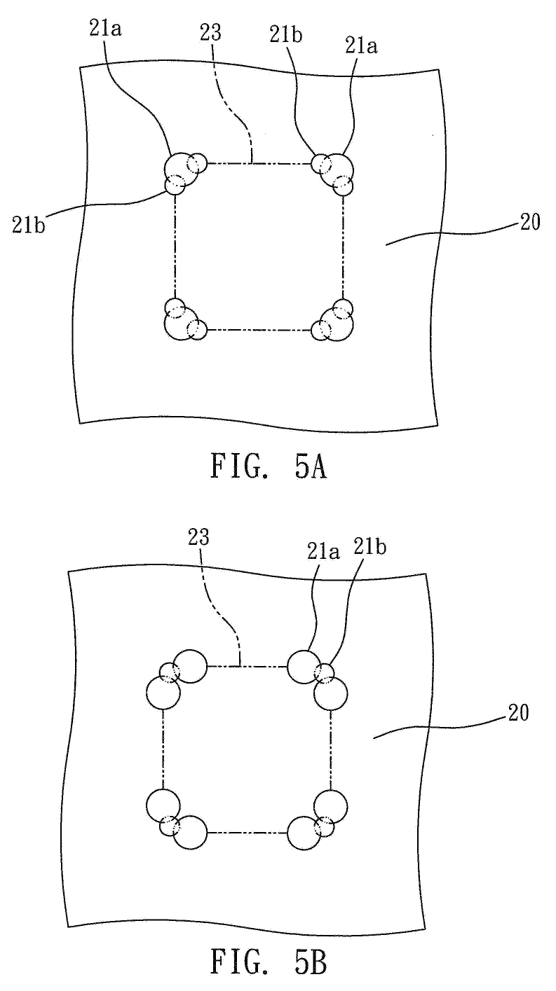

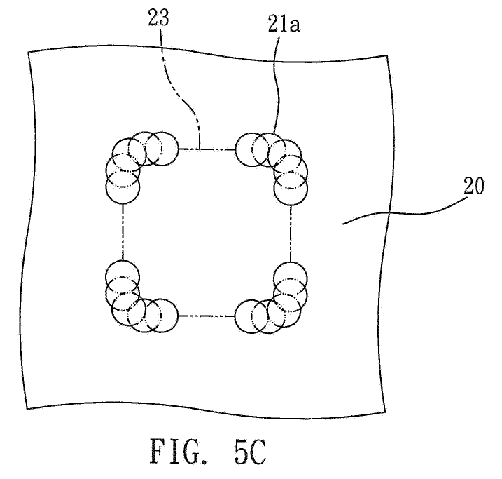

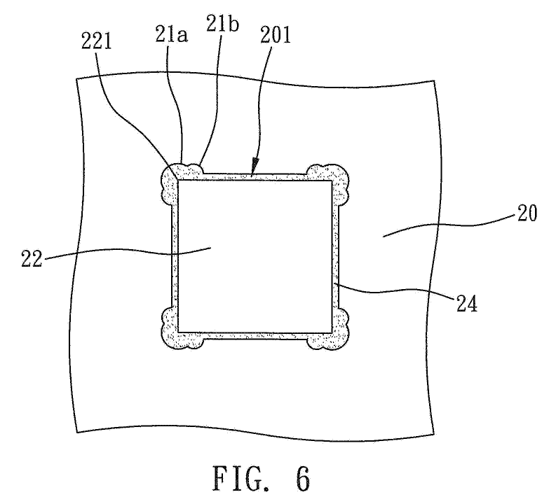

FIGS. 5A to 5C, and FIG. 6 are top views showing the fabricating method of a carrier board with a semiconductor chip embedded therein, in accordance with the second preferred embodiment of the invention. The difference between this embodiment and the foregoing first embodiment is that breaches are formed on the carrier board before forming the rectangular cavity.

As shown in FIGS. 5A to 5C, a carrier board 20 is provided. Breaches extending from predetermined positions 23 corresponding to the corners of the rectangular cavity to be formed in the carrier board 20 are formed. The breaches are formed by means of mechanical drilling, laser drilling, or pressing, and can be in a form of a combination of a large drilling hole 21a and two small drilling holes 21b adjacent to the large drilling hole 21a (as shown in FIG. 5A), or a combination of a small drilling hole 21b and two large drilling holes 21a adjacent to the small drilling hole 21b (as shown in FIG. 5B), or formed by a plurality of large drilling holes 21a (as shown in FIG. 5C). The carrier board 20 is one selected from the group consisting of an insulation board, a metallic board, and a circuit board finished with front-end wiring processes.

Subsequently, as shown in FIG. 6, illustrated based on the carrier board of FIG. 5A, a rectangular cavity 201 is formed by means of mechanical drilling or laser drilling at locations of the carrier board 20 corresponding to the predetermined positions 23, allowing the large drilling holes 21a to be formed at the corners of the rectangular cavity 201.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A carrier board structure with a semiconductor chip embedded therein comprising:
a carrier board;
at least one rectangular cavity formed in the carrier board;
at least one breach formed at a corner or corners of the rectangular cavity the breach being composed of a plurality of drilling holes;
a semiconductor chip disposed into the rectangular cavity; and
an adhesive material formed in a gap between the rectangular cavity of the carrier board and the semiconductor chip to secure in position the semiconductor chip in the rectangular cavity.

2. The carrier board structure with a semiconductor chip embedded therein of claim 1, wherein the carrier board is one selected from the group consisting of an insulation board, a metallic board and a circuit board finished with front-end wiring processes.

3. The carrier board structure with a semiconductor chip embedded therein of claim 1, wherein the gap formed between the semiconductor chip and the rectangular cavity is in a range of from 10 μm to 200 μm.

4. The carrier board structure with a semiconductor chip embedded therein of claim 1, wherein the plurality of drilling holes comprise at least a large drilling hole and at least two small drilling holes adjacent to the large drilling hole.

5. The carrier board structure with a semiconductor chip embedded therein of claim 1 wherein the plurality of drilling holes comprise at least a small drilling hole and at least two large drilling holes adjacent to the small drilling hole.

6. The carrier board structure with a semiconductor chip embedded therein of claim 1, wherein the plurality of drilling holes comprise a plurality of large drilling holes.

7. The carrier board structure with a semiconductor chip embedded therein of claim 1, wherein the breach is formed by one selected from the group consisting of a mechanical drilling process, a laser drilling process, and a pressing process.

8. The carrier board structure with a semiconductor chip embedded therein of claim 1, wherein the rectangular cavity is formed by one of a mechanical drilling process and a laser drilling process.

9. A carrier board structure, comprising:
a carrier board;
at least one rectangular cavity formed in the carrier board; and
at least one breach formed at a corner or corners of the rectangular cavity, the breach being composed of a plurality of drilling holes.

10. The carrier board structure of claim 9, wherein the carrier board is one selected from the group consisting of an insulation board, a metallic board, and a circuit board finished with front-end wiring processes.

11. The carrier board structure of claim 9, wherein a semiconductor chip is disposed into the rectangular cavity.

12. The carrier board structure of claim 11, further comprising an adhesive material formed in a gap between the rectangular cavity of the carrier board and the semiconductor chip.

13. The carrier board structure of claim 12, wherein the gap formed between the semiconductor chip and the rectangular cavity is in a range of from 10 μm to 200 μm.

14. The carrier board structure of claim 9, wherein the plurality of drilling holes comprise at least a large drilling hole and at least two small drilling holes adjacent to the large drilling hole.

15. The carrier board structure of claim 9, wherein the plurality of drilling holes comprises at least a small drilling hole and at least two large drilling holes adjacent to the small drilling hole.

16. The carrier board structure of claim 9, wherein the plurality of drilling holes comprise a plurality of large drilling holes.

17. The carrier board structure of claim 9, wherein the breach is formed by one selected from the group consisting of a mechanical drilling process, a laser drilling process, and a pressing process.

18. The carrier board structure of claim 9, wherein the rectangular cavity is formed by one of a mechanical drilling process and a laser drilling process.

19. A fabricating method of a carrier board structure with a semiconductor chip embedded therein, comprising the steps of:
providing a carrier board;
forming at least a rectangular cavity at a predetermined position or predetermined positions of the carrier board;
forming at least a breach at a corner or corners of the rectangular cavity, the breach being composed of a plurality of drilling holes;
disposing a semiconductor chip into the rectangular cavity; and
forming an adhesive material in a gap formed between the rectangular cavity of the carrier board and the semiconductor chip to secure in position the semiconductor chip in the rectangular cavity.

20. The fabricating method of a carrier board structure with a semiconductor chip embedded therein of claim 19, wherein the carrier board is one selected from the group consisting of an insulation board, a metallic board, and a circuit board finished with front-end wiring processes.

21. The fabricating method of a carrier board structure with a semiconductor chip embedded therein of claim 19, wherein the gap formed between the semiconductor chip and the rectangular cavity is in a range of from 10 μm to 200 μm.

22. The fabricating method of a carrier board structure with a semiconductor chip embedded therein of claim 19, wherein the plurality of drilling holes comprise at least a large drilling hole and at least two small drilling holes adjacent to the large drilling hole.

23. The fabricating method of a carrier board structure with a semiconductor chip embedded therein of claim 19, wherein the plurality of drilling holes comprise at least a small drilling hole and at least two large drilling holes adjacent to the small drilling hole.

24. The fabricating method of a carrier board structure with a semiconductor chip embedded therein of claim 19, wherein the plurality of drilling holes comprise a plurality of large drilling holes.

25. The fabricating method of a carrier board structure with a semiconductor chip embedded therein of claim 19, wherein the breach is formed by one selected from the group consisting of a mechanical drilling process, a laser drilling process, and a pressing process.

26. The fabricating method of a carrier board structure with a semiconductor chip embedded therein of claim 19, wherein the rectangular cavity is formed by one of a mechanical drilling process and a laser drilling process.

27. The fabricating method of a carrier board structure with a semiconductor chip embedded therein, comprising the steps of:
providing a carrier board;
forming at least a breach at a corner or corners of a rectangular cavity to be formed in the carrier board at a predetermined position the breach being composed of a plurality of drilling holes;
forming the rectangular cavity in the carrier board at the predetermined position;
disposing a semiconductor chip into the rectangular cavity; and
forming an adhesive material in a gap formed between the rectangular cavity of the carrier board and the semiconductor chip to secure in position the semiconductor chip in the rectangular cavity.

28. The fabricating method of a carrier board structure with a semiconductor chip embedded therein of claim 27, wherein the carrier board is one selected from the group consisting of an insulation board, a metallic board and a circuit board finished with front-end wiring processes.

29. The fabricating method of a carrier board structure with a semiconductor chip embedded therein of claim 27, wherein the gap formed between the semiconductor chip and the rectangular cavity is in a range of from 10 μm to 200 μm.

30. The fabricating method of a carrier board structure with a semiconductor chip embedded therein of claim 27, wherein the plurality of drilling holes comprise at least a large drilling hole and at least two small drilling holes adjacent to the large drilling hole.

31. The fabricating method of a carrier board structure with a semiconductor chip embedded therein of claim 27, wherein the plurality of drilling holes comprise at least a small drilling hole and at least two large drilling holes adjacent to the small drilling hole.

32. The fabricating method of a carrier board structure with a semiconductor chip embedded therein of claim 27, wherein the plurality of drilling holes comprise a plurality of large drilling holes.

33. The fabricating method of a carrier board structure with a semiconductor chip embedded therein of claim 27, wherein the breach is formed by one selected from the group consisting of a mechanical drilling process, a laser drilling process, and a pressing process.

34. The fabricating method of a carrier board structure with a semiconductor chip embedded therein of claim 27, wherein the rectangular cavity is formed by one of a mechanical drilling process and a laser drilling process.
